(19) United States
(12) Patent Application Publication
(10) Pub. No.: US 2024/0243067 A1
(43) Pub. Date: Jul. 18, 2024

(54) CHIP-ON-FILM STRUCTURE, DISPLAY DEVICE AND SPLICED DISPLAY DEVICE

(71) Applicant: XIAMEN EXTREMELY PQ DISPLAY TECHNOLOGY CO., LTD., Xiamen (CN)

(72) Inventors: Yong FAN, Xiamen (CN); CHEN-KE HSU, Xiamen (CN)

(21) Appl. No.: 18/429,625

(22) Filed: Feb. 1, 2024

Related U.S. Application Data
(63) Continuation-in-part of application No. PCT/CN2021/139166, filed on Dec. 17, 2021.

(30) Foreign Application Priority Data
Dec. 7, 2021 (CN) 202111484204.3
Dec. 12, 2023 (CN) 202323389960.5

(51) Int. Cl. H01L 23/538; H01L 23/00; H01L 23/31; H01L 25/16

(52) U.S. Cl. CPC H01L 23/5384; H01L 23/3157; H01L 23/5386; H01L 24/05; H01L 24/16; H01L 25/167; H01L 2224/05541; H01L 2224/05573; H01L 2224/16225; H01L 2224/16235; H01L 2924/1426

(57) ABSTRACT

Embodiments of the present application disclose a chip-on-film structure, a display device, and a spliced display device. The chip-on-film structure includes: a substrate having a first surface and a second surface oppositely disposed; a first circuit covering the first surface, wherein the first circuit includes a driving chip bonding area; a display panel bonding end disposed on the second surface; and a first conductive portion connected to the first circuit and the display panel bonding end respectively.

### CROSS-REFERENCE TO RELATED APPLICATIONS

This application is a continuation-in-part of International Application No. PCT/CN2021/139166, filed on Dec. 17, 2021, which claims priority to Chinese Patent Application No. 202111484204.3, filed on Dec. 7, 2021, and Chinese Patent Application No. 202323389960.5, filed on Dec. 12, 2023. All of the aforementioned patent applications are hereby incorporated by reference in their entireties.

### TECHNICAL FIELD

Embodiments of the present application relate to a technical field of a display panel, and more particularly, to a chip-on-film structure, a display device, and a spliced display device.

### BACKGROUND

Currently, in a display device, a driving chip and a display panel are bonded to a same side of a chip-on-film (COF) structure, and the driving chip is disposed between the display panel and the chip-on-film structure. Due to a higher height of the driving chip, a height of a metal welding layer bonded to the display panel and the chip-on-film structure is high, resulted in that the bonding difficulty is high, the reliability problem easily occurs, and the bonding yield is affected. In addition, the heat is generated during operation of the driving chip, which causes the temperature of an area of the display panel close to the driving chip to rise, and further causes the light-emitting efficiency and the brightness of the light-emitting devices in the display panel to decrease, and causes uneven display of the display panel.

### SUMMARY

Embodiments of the present application provide a chip-on-film structure including: a base, where the base includes a first surface and a second surface oppositely disposed; a first circuit covering the first surface, where the first circuit includes a driving chip bonding area; a display panel bonding end disposed on the second surface; and a first conductive portion connected to the first circuit and the display panel bonding end respectively.

In some embodiments, the first conductive portion extends through the base.

In some embodiments, the base further includes a third surface and a fourth surface, the third surface is connected to the first surface and the second surface, the fourth surface is connected to the first surface and the second surface; and the first conductive portion covers the third surface.

In some embodiments, the display panel bonding end and the first conductive portion are overlapped in a target direction, and the target direction is parallel to the second surface.

In some embodiments, the display panel bonding end is spaced apart from the first conductive portion in a target direction, and the target direction is parallel to the second surface; where the chip-on-film structure further includes a second circuit, the second circuit at least partially covers the second surface, the display panel bonding end is disposed on a side of the second circuit away from the base, and the first conductive portion is connected to the display panel bonding end through the second circuit.

In some embodiments, the chip-on-film structure further includes a heat insulating layer; and the heat insulating layer is disposed on a side of the second circuit away from the base.

In some embodiments, the chip-on-film structure further includes a first protective layer; and the first protective layer is disposed on a side of the first circuit away from the base.

In some embodiments, the chip-on-film structure further includes a second protective layer; and the second protective layer is positioned between the second circuit and the heat insulating layer.

In some embodiments, the first circuit further includes a circuit board bonding area; and the circuit board bonding area and the display panel bonding end are respectively disposed close to opposite ends of the base.

In some embodiments, the chip-on-film structure further includes a driving chip and a circuit board, the driving chip is disposed in the driving chip bonding area and is connected to the first circuit, and the circuit board is disposed in the circuit board bonding area and is connected to the first circuit.

Embodiment of the present application further provide a display device including the chip-on-film structure described above; and a display panel, where the display panel is connected to the display panel bonding end in the chip-on-film structure.

In some embodiments, the display panel is a top light-emitting display panel, and the display panel includes a second conductive portion; where a top of the light-emitting display panel has a second bonding end, the chip-on-film structure is disposed at bottom of the top light-emitting display panel, and the display panel bonding end faces the display panel and is connected to the second bonding end through the second conductive portion; and where the second conductive portion extends through the display panel or covers a side surface of the display panel.

In some embodiments, the display panel is a bottom light-emitting display panel; where a top of the bottom light-emitting display panel has a first bonding end, the chip-on-film structure is disposed on top of the display panel, and the display panel bonding end faces the display panel and is connected to the first bonding end.

In some embodiments, the display panel includes: a driving backplane, where the driving backplane includes a plurality of bonding electrode pairs, each of the plurality of bonding electrode pairs includes a first bonding electrode and a second bonding electrode insulated from each other; and light-emitting devices, where each of the light-emitting devices is bonded to the driving backplane through a corresponding pair of the plurality of bonding electrode pairs, the light-emitting device includes a first electrode and a second electrode insulated from each other, the first electrode is electrically connected to the first bonding electrode, and the second electrode is electrically connected to the second bonding electrode; where a light-emitting surface of the light-emitting device faces the driving backplane, the light-emitting device further includes an epitaxial plate, and the first electrode and the second electrode are both disposed on a side of the epitaxial plate away from the driving backplane.

In some embodiments, the display panel further includes a first connection line connected between the first electrode and the first bonding electrode, and a second connection line connected between the second electrode and the second bonding electrode.

In some embodiments, the light-emitting device further includes an insulating protective layer covering the epitaxial plate and exposing the first electrode and the second electrode, and the first connection line and the second connection line both are provided on a side of the insulating protective layer away from the epitaxial plate.

In some embodiments, the epitaxial plate includes an N-type semiconductor layer, a P-type semiconductor layer, and a quantum well layer disposed between the N-type semiconductor layer and the P-type semiconductor layer; the P-type semiconductor layer is disposed on a side of the N-type semiconductor layer away from the driving backplane; the first electrode is electrically connected to the N-type semiconductor layer; and the second electrode is electrically connected to the P-type semiconductor layer.

In some embodiments, the N-type semiconductor layer includes a projection beyond a boundary of the quantum well layer, the first electrode is provided on a side of the projection away from the driving backplane, and the second electrode is provided on a side of the P-type semiconductor layer away from the quantum well layer.

In some embodiments, the driving backplane further includes a substrate, and a transistor disposed on the substrate; the first bonding electrode and the bonding second electrode both are disposed on a side of the transistor away from the substrate; and the first bonding electrode is electrically connected to the transistor. Embodiments of the present application further provide a spliced display device including a plurality of the display devices.

### Beneficial Effect

The first circuit covers the first surface of the base, the first circuit includes a driving chip bonding area, the display panel bonding end is provided on the second surface of the base, the first surface is provided opposite to the second surface, and the first circuit is connected to the display panel bonding end through the first conductive portion, so as to ensure that the driving chip and the display panel are bonded to both opposite sides of the base respectively, to avoid that the display panel bonding end is too high, and to reduce the bonding difficulty of the display panel, improve the bonding efficiency and reliability, facilitate heat dissipation of the driving chip, and improve the uneven display of the display panel due to the heating from the driving chip.

In addition, in the bottom light-emitting display panel, the light-emitting surface of the light-emitting device faces the driving backplane, and the first electrode and the second electrode of the light-emitting device are both disposed on the side of the epitaxial plate away from the driving backplane. In this way, the first electrode and the second electrode do not block the light emitted from the light-emitting device, so that the light output utilization rate of the bottom light-emitting display panel can be improved, and the situation that the light output utilization rate is low due to the fact that the bottom electrode of the flip chip in the bottom light-emitting display panel blocks out the light from the chip is improved.

### BRIEF DESCRIPTION OF THE DRAWINGS

In order that the embodiments or the technical solutions in the related art may be described more clearly, reference will now be made to the accompanying drawings which are to be used in the description of the embodiment. It should be understood that the accompanying drawings in the description below are merely some of the embodiments of the present application, and other drawings may be made to those skilled in the art without involving any inventive effort.

FIG. 1 is a schematic structural diagram of a display device according to related art according to an embodiment of the present application;

FIG. 2 is a schematic structural diagram of a chip-on-film structure according to an embodiment of the present application;

FIG. 3 is another schematic structural diagram of a chip-on-film structure according to an embodiment of the present application;

FIG. 4 is yet another schematic structural diagram of a chip-on-film structure according to an embodiment of the present application;

FIG. 5 is yet another schematic structural diagram of a chip-on-film structure according to an embodiment of the present application;

FIG. 6 is yet another schematic structural diagram of a chip-on-film structure according to an embodiment of the present application;

FIG. 7 is a schematic structural diagram of a display device according to an embodiment of the present application;

FIG. 8 is another schematic structural diagram of a display device according to an embodiment of the present application;

FIG. 9 is yet another schematic structural diagram of a display device according to an embodiment of the present application;

FIG. 10 is yet another schematic structural diagram of a display device according to an embodiment of the present application;

FIG. 11 is yet another schematic structural diagram of a display device according to an embodiment of the present application;

FIG. 12 is yet another schematic structural diagram of a display device according to an embodiment of the present application;

FIG. 13 is yet another schematic structural diagram of a display device according to an embodiment of the present application;

FIG. 14 is yet another schematic structural diagram of a display device according to an embodiment of the present application;

FIG. 15 is yet another schematic structural diagram of a display device according to an embodiment of the present application;

FIG. 16 is yet another schematic structural diagram of a display device according to an embodiment of the present application;

FIG. 17 is a schematic structural diagram of a bottom light-emitting display panel according to an embodiment of the present application;

FIG. 18 is a schematic structural diagram of details of a light-emitting device of FIG. 17; and

FIG. 19 is a schematic structural diagram of a spliced display device according to an embodiment of the present application.

### DETAILED DESCRIPTION OF THE EMBODIMENTS

The specific structural and functional details disclosed herein are representative only and are for the purpose of describing exemplary embodiments of the present application. The present application may, however, be embodied in many alternative forms and should not be construed as limited only to the embodiments set forth herein.

In the description of the present application, it should be understood that the orientation or positional relationship indicated by the terms “center”, “lateral”, “on”, “below”, “left”, “right”, “vertical”, “horizontal”, “top”, “bottom”, “in”, “out”, and the like, is based on the orientation or positional relationship shown in the drawings, merely to facilitate the description of the present application and to simplify the description, and not to indicate or imply that the device or element referred to must have a particular orientation, be constructed and operated in a particular orientation, and therefore is not to be construed as limiting the present application. Furthermore, the terms “first” and “second” are used for descriptive purposes only and are not to be construed as indicating or implying relative importance or implying the number of indicated technical features. Thus, the features defined by “first” and “second” are indicated or implied to include one or more. In the description of this application, unless otherwise stated, “a plurality of” means two or more. Additionally, the term “comprise” and any variations thereof is intended to cover a non-exclusive inclusion.

In the description of the present application, it should be noted that, unless expressly stated and defined otherwise, the terms “mount”, “link”, “connect” are to be understood in a broad sense, for example, as a fixed connection, as a detachable connection, or as an integrated connection; as a mechanical connection or an electrical connection; as a directly connection or an indirectly connection by means of an intermediate medium; and as an internal communication of the two elements. The specific meaning of the above terms in the present application can be understood in a specific way to those of ordinary skill in the art.

The terms used herein is for the purpose of describing specific embodiments only and is not intended to limit the exemplary embodiments. As used herein, the singular forms “a”, and “an” are also intended to include the plural unless the context clearly dictates otherwise. It should be understood that the terms used herein “comprise” and/or “include” specifies the presence of stated features, integers, steps, operations, units, and/or components, without the presence or addition of one or more other features, integers, steps, operations, units, components, and/or combinations thereof.

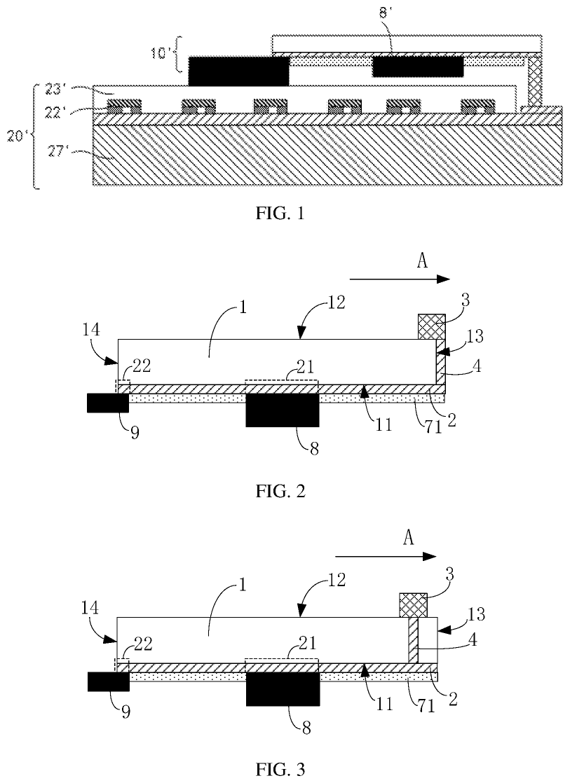

FIG. 1 is a schematic structural diagram of a display device according to related art. The display device includes a display panel 20′, and a chip-on-film (COF) structure 10′ bonded to the display panel 20′. The display device further includes a driving chip 8′, the driving chip 8′ and the display panel 20′ are bonded to a same side of the chip-on-film structure 10′, and the driving chip 8′ is disposed between the display panel 20′ and the chip-on-film structure 10′. Due to a higher height of the driving chip 8′, a height of a metal welding layer bonded to the display panel 20′ and the chip-on-film structure 10′ is high, resulted in that the bonding difficulty is high, the reliability problem easily occurs, and the bonding yield is affected.

Referring to FIG. 2 to FIG. 6, embodiments of the present application provide a chip-on-film structure to alleviate the above problems.

As shown in FIG. 2 to FIG. 6, embodiments of the present application provide a chip-on-film structure including a base 1, a first circuit 2, a display panel bonding end 3, and a first conductive portion 4. The base 1 includes a first surface 11, a second surface 12, a third surface 13, and a fourth surface 14. The first surface 11 and the second surface 12 are oppositely arranged, and the third surface 13 and the fourth surface 14 are respectively connected between the first surface 11 and the second surface 12. The first surface 11 may be a lower surface of the base 1, and the second surface 12 may be an upper surface of the base 1. Meanwhile, the third surface 13 is disposed opposite to the fourth surface 14, and both the third surface 13 and the fourth surface 14 may be side surfaces of the base 1. The base 1 may be a PI (polyimide) base.

The first circuit 2 covers the first surface 11 of the base 1, and the first circuit 2 may cover the first surface 11 of the base 1 in whole or in part. The material of the first circuit 2 is a conductive metal such as tungsten, cobalt, copper, aluminum, or the like. The first circuit 2 includes a driving chip bonding area 21 and a circuit board bonding area 22, and the chip-on-film structure may further include a driving chip 8 and a circuit board 9. The driving chip 8 is disposed in the driving chip bonding area 21, and is connected to the first circuit 2 to bond with the first circuit 2. The circuit board 9 is disposed in the circuit board bonding area 22, and is connected to the first circuit 2 to bond with the first circuit 2. As shown in FIG. 2 to FIG. 6, the driving chip bonding area 21 may be disposed close to the center area of the first surface 11. The circuit board bonding area 22 and the display panel bonding end 3 are disposed close to opposite ends of the base 1, respectively. For example, the display panel bonding end 3 is disposed close to the third surface 13 of the base 1, and the circuit board bonding area 22 is disposed close to the fourth surface 14 of the base 1.

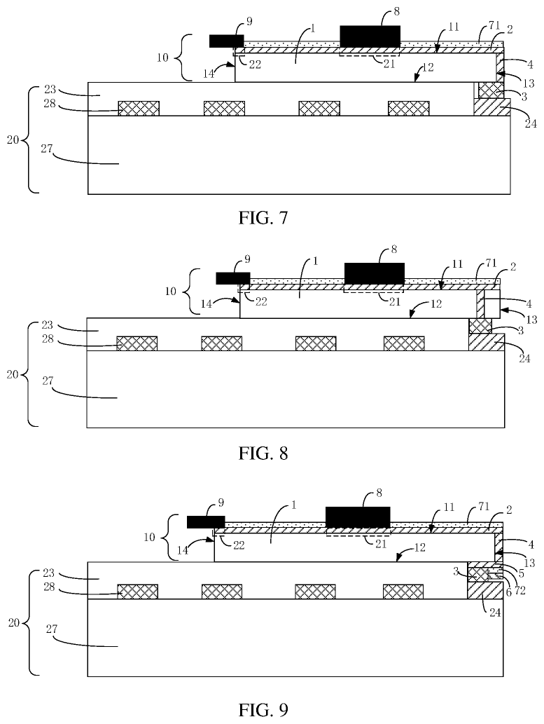

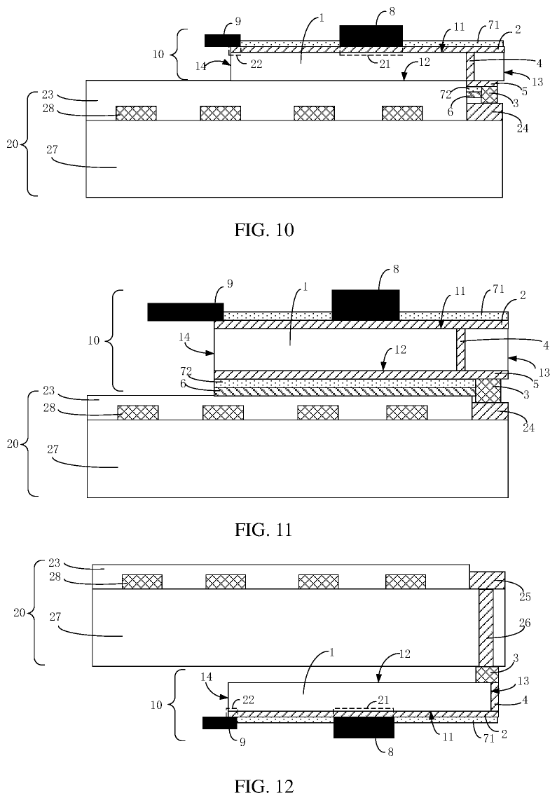

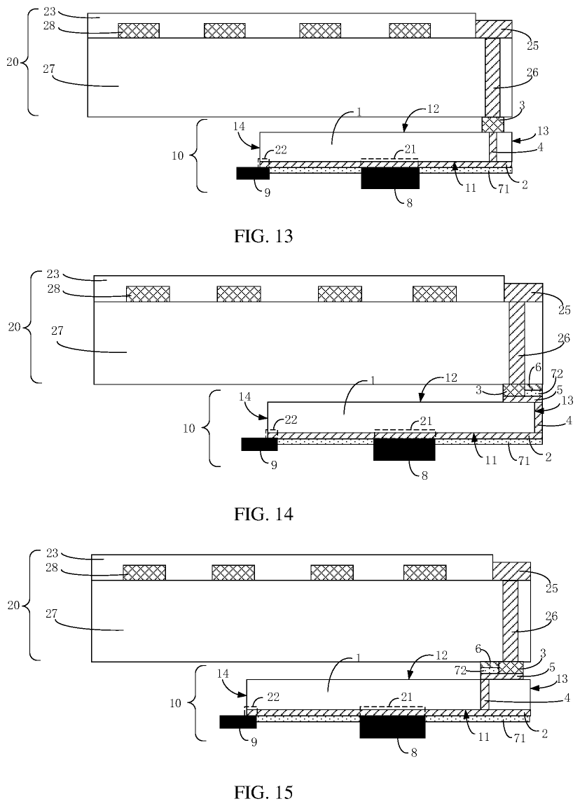

The display panel bonding end 3 is disposed on the second surface 12 of the base 1 for bonding with the display panel 20 (as will be described below with reference to FIG. 7 to FIG. 16). As shown in FIG. 2, the display panel bonding end 3 is provided close to an end of the base 1, for example, the display panel bonding end 3 is provided close to the third surface 13 of the base 1. The display panel bonding end 3 may be a solder metal, and the solder metal may be a conductive metal such as tungsten, cobalt, copper, aluminum, or the like.

The first conductive portion 4 is connected to the first circuit 2 and the display panel bonding end 3, that is, an end of the first conductive portion 4 is connected to the first circuit 2, and another end of the first conductive portion 4 is connected to the display panel bonding end 3. After bonding the driving chip 8 and the display panel 20 (see FIG. 7 to FIG. 16), the driving chip 8 may be electrically connected to the display panel 20 through the first circuit 2, the first conductive portion 4, and the display panel bonding end 3. The material of the first conductive portion 4 is a conductive metal such as tungsten, cobalt, copper, aluminum, or the like.

In this embodiment, the driving chip bonding area 21 is disposed on the first surface 11 of the base 1, and the display panel bonding end 3 is disposed on the second surface 12 of the base 1, that is, the driving chip bonding area 21 and the display panel bonding end 3 are disposed on opposite sides of the base 1. Thus, after bonding the driving chip and the display panel, the driving chip and the display panel are disposed on opposite sides of the base 1. In this way, the height of the display panel bonding end 3 does not need to set high, for example, it can be less than the height of the driving chip, thereby reducing the bonding difficulty of the display panel and improving the bonding yield and reliability. In addition, the driving chip and the display panel are disposed on opposite sides of the base 1 to facilitate heat dissipation of the driving chip, and the heating from the driving chip does not affect the display panel, thereby improving the display evenness of the display panel.

In addition, as shown in FIG. 2 to FIG. 6, the chip-on-film structure may further include a first protective layer 71 disposed on a side of the first circuit 2 away from the base 1. The first protective layer 71 may cover the areas on the first circuit 2 except the driving chip bonding area 21 and the circuit board bonding area 22, so that the first protective layer 71 can protect the first circuit 2.

In an embodiment, as shown in FIG. 2, the first circuit 2 covers the first surface 11 of the base 1, the first conductive portion 4 covers the third surface 13 of the base 1, and an end of the first conductive portion 4 is connected to the first circuit 2. The display panel bonding end 3 is disposed on the second surface 12 of the base 1, and the display panel bonding end 3 and the first conductive portion 4 are overlapped in a target direction A (i.e., a direction parallel to the second surface 12). That is, the display panel bonding end 3 is disposed close to the third surface 13 of the base 1, so that another end of the first conductive portion 4 is directly connected to the display panel bonding end 3. According to the present embodiment, the display panel bonding end 3 is directly provided on the second surface 12 of the base 1, the thickness of the chip-on-film structure is reduced, and the height of the display panel bonding end 3 can be reduced as much as possible, the bonding difficulty of the display panel can be reduced, and the bonding yield and reliability can be improved.

In another embodiment, as shown in FIG. 3, the first circuit 2 covers the first surface 11 of the base 1, the first conductive portion 4 extends through the base 1, and an end of the first conductive portion 4 is connected to the first circuit 2. The display panel bonding end 3 is disposed on the second surface 12 of the base 1, and the display panel bonding end 3 and the first conductive portion 4 are overlapped in the target direction A, so that another end of the first conductive portion 4 is directly connected to the display panel bonding end 3. In the present embodiment, the thickness of the chip-on-film structure is reduced, and the height of the display panel bonding end 3 is reduced as much as possible, so that the first conductive portion 4 can be prevented from being exposed, thereby preventing the first conductive portion 4 from being short-circuited with other conductive structures.

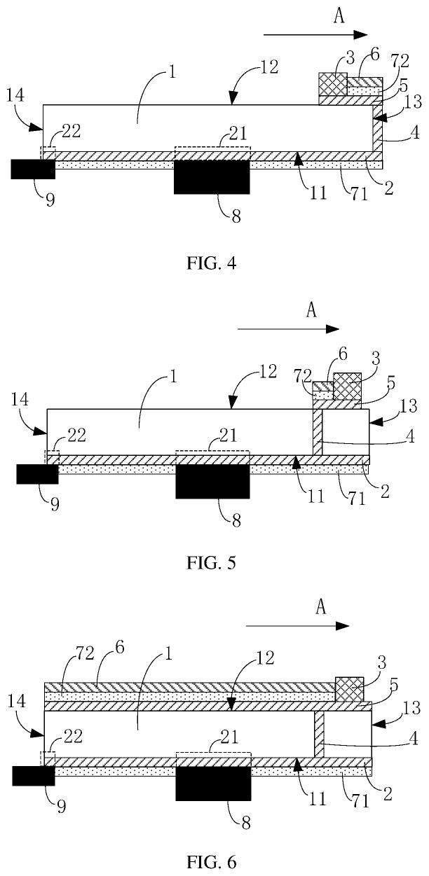

In another embodiment, as shown in FIG. 4, the first circuit 2 covers the first surface 11 of the base 1, the first conductive portion 4 covers the third surface 13 of the base 1, and an end of the first conductive portion 4 is connected to the first circuit 2. The display panel bonding end 3 and the first conductive portion 4 are spaced from each other in the target direction A, the second surface 12 of the base 1 is partially covered by the second circuit 5, and another end of the first conductive portion 4 is connected to the display panel bonding end 3 through the second circuit 5. In this embodiment, the height of the bonding end 3 of the display panel can be reduced while increasing the area in which the display panel bonding end 3 can be provided on the second surface 12, thereby reducing the process difficulty of the display panel bonding end 3.

In another embodiment, as shown in FIG. 5, the first circuit 2 covers the first surface 11 of the base 1, the first conductive portion 4 extends through the base 1, and an end of the first conductive portion 4 is connected to the first circuit 2. The display panel bonding end 3 and the first conductive portion 4 are spaced from each other in the target direction A, the second surface 12 of the base 1 is partially covered by the second circuit 5, and another end of the first conductive portion 4 is connected to the display panel bonding end 3 through the second circuit 5. In this embodiment, the height of display panel the bonding end 3 can be reduced, and the process difficulty of the display panel bonding end 3 can be reduced. At the same time, the first conductive portion 4 can be prevented from being exposed, thereby preventing the first conductive portion 4 from being short-circuited with other conductive structures.

In another embodiment, as shown in FIG. 6, the first circuit 2 covers the first surface 11 of the base 1, the second surface 12 of the base 1 is covered by the second circuit 5 in whole, the display panel bonding end 3 is disposed on the side of the second circuit 5 away from the base 1, and the first conductive portion 4 can extend through the base 1 or the third surface 13 of the base 1. Thus, an end of the first conductive portion 4 is connected to the first circuit 2, and another end of the first conductive portion 4 is connected to the display panel bonding end 3 through the second circuit 5. The first conductive portion 4 and the display panel bonding end 3 may be overlapped in the target direction A, or may be spaced from each other in the target direction A. In manufacturing the second circuit 5 of the present embodiment, the second circuit 5 is completely covered on the second surface 12 of the base 1 without etching the second circuit 5, so that the manufacturing process of the second circuit 5 is simplified while the height of the display panel bonding end 3 is reduced and the process difficulty of the display panel bonding end 3 is reduced.

As shown in FIG. 4 to FIG. 6, the chip-on-film structure may further include a heat insulating layer 6 disposed on the side of the second circuit 5 away from the base 1. The heat insulating layer 6 may cover the areas on the second circuit 5 except the area connected with the display panel bonding end 3, to insulate the heat generated by the second circuit 5. As such, after bonding, the display panel can be prevented from being affected by the heat generated by the second circuit 5. Thus, the uneven display of the display panel due to the heating from the second circuit 5 can be avoided.

As shown in FIG. 4 to FIG. 6, the chip-on-film structure may further include a second protective layer 72 disposed between the second line 5 and the heat insulating layer 6. The second protective layer 72 may cover the areas on the second circuit 5 except the area connected with the display panel bonding end 3, so that the second protective layer 72 can protect the second circuit 5. The heat insulating layer 6 may completely cover the second protective layer 72 to ensure effective insulation of the heat generated by the second circuit 5.

According to the chip-on-film structure provided in the embodiments of the present application, the first circuit is covered on the first surface of the base, the first circuit includes a driving chip bonding area, the display panel bonding end is provided on the second surface of the base, the first surface is disposed opposite to the second surface, and the first circuit is connected to the display panel bonding end through the first conductive portion, so that the driving chip and the display panel are bonded to opposite sides of the base, to avoid that the display panel bonding end is too high, to reduce the bonding difficulty of the display panel, improve the bonding efficiency and reliability, facilitate heat dissipation of the driving chip, and improve the display evenness of the display panel.

Referring to FIG. 7 to FIG. 16, embodiments of the present application further provides a display device including the above-described chip-on-film structure 10 and a display panel 20, and the display panel 20 may be a bottom light-emitting display panel or a top light-emitting display panel. The display panel bonding end 3 in the chip-on-film structure 10 is disposed facing the display panel 20, and the chip-on-film structure 10 is connected to the display panel 20 through the display panel bonding end 3, so that the chip-on-film structure 10 is bonded to the display panel 20.

In a case that the display panel 20 is a bottom light-emitting display panel, as shown in FIG. 7 to FIG. 11, the top of the display panel 20 has a first bonding end 24, the chip-on-film structure 10 is disposed on the top of the display panel 20, and the display panel bonding end 3 in the chip-on-film structure 10 is connected to the first bonding end 24.

At this time, the display panel 20 includes a driving backplane 27, light-emitting devices 28 disposed on the driving backplane 27, and an encapsulation layer 23 covering the light-emitting devices 28 and the driving backplane 27. The encapsulation layer 23 serves to reflect the lights emitted by the light-emitting devices 28 to the bottom of the display panel 20 (i.e., a side of the driving backplane 27 away from the encapsulation layer 23) in addition to the encapsulation. The first bonding end 24 may be disposed on the driving backplane 27, and the encapsulation layer 23 does not cover the first bonding end 24.

In a case that the display panel 20 is a top light-emitting display panel, as shown in FIG. 12 to FIG. 16, the top of the display panel 20 has a second bonding end 25, and a second conductive portion 26 connected to the second bonding end 25. The chip-on-film structure 10 is disposed at the bottom of the display panel 20, and the display panel bonding end 3 in the display panel 20 is connected to the second bonding end 25 through the second conductive portion 26. The second conductive portion 26 may extend through the display panel 20, or may cover a side surface of the display panel 20.

At this time, the display panel 20 may include a driving backplane 27, light-emitting devices 28 disposed on the driving backplane 27, and an encapsulation layer 23 covering the light-emitting devices 28 and the driving backplane 27. The encapsulation layer 23 is used to encapsulate the light-emitting devices 28.

The second bonding end 25 may be disposed on the driving backplane 27, and the encapsulation layer 23 may not cover the second bonding end 25. In other embodiments, the encapsulation layer 23 may cover the second bonding end 25.

According to the display device provided in the embodiment of the present application, the driving chip and the display panel can be bonded to opposite sides of the base, so that the height of the display panel bonding end is prevented from being too high, the bonding difficulty of the display panel is reduced, the bonding yield and the reliability are improved, the heat dissipation of the driving chip is facilitated, and the uneven display of the display panel caused by the heating of the driving chip is improved.

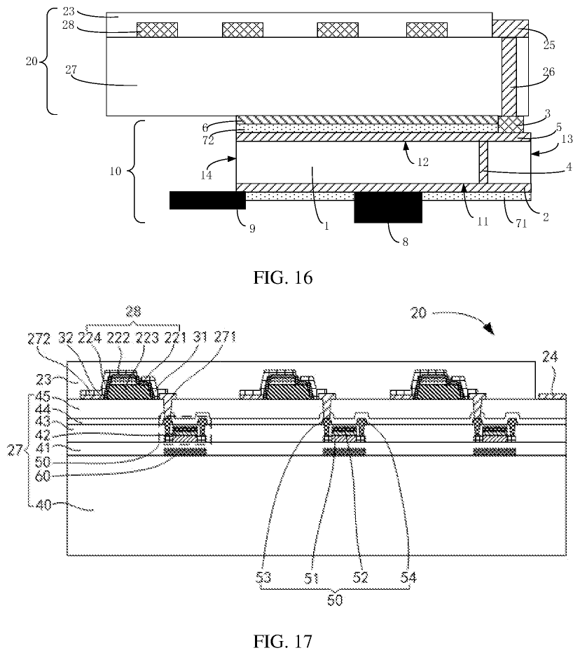

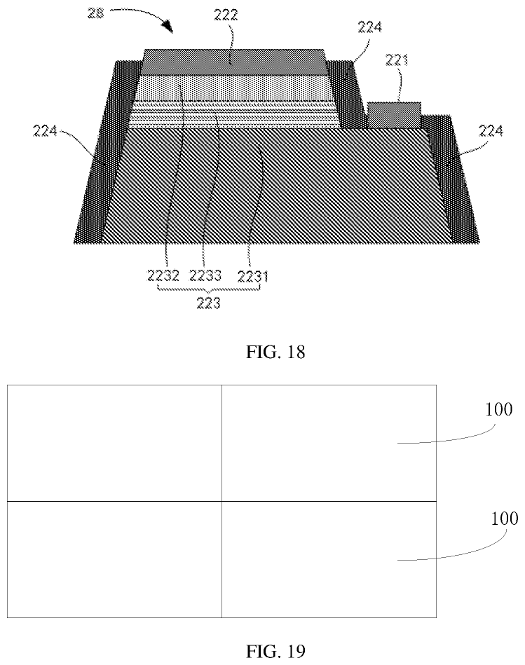

Embodiments of the present application provides a specific structure of the bottom light-emitting display panel as shown in FIG. 7 to FIG. 11. Referring back to the display device of FIG. 1 in the related art, in a case that the display panel 20′ is a bottom light-emitting display panel, the light-emitting surfaces of the light-emitting devices 22′ face away from the driving backplane 27′, and the lights emitted from the light-emitting devices 22′ are reflected by the encapsulation layer 23′ and go out from the driving backplane 27′. However, since the light-emitting devices 22′ of the display device adopt a conventional flip chip structure, the lights emitted from the back surfaces of the light-emitting devices 22′ need to be reflected by the encapsulation layer at the front and then are emitted downward. Moreover, the light-emitting devices 22′ are shielded from the bottom electrode of the flip chip, thereby reducing the utilization rate of the reflected light. Based on this, an embodiment of the present application provides a bottom light-emitting display panel as shown in FIG. 17 to FIG. 18 to solve the above problems.

Referring to FIG. 17 and FIG. 18, FIG. 17 is a schematic structural diagram of a bottom light-emitting display panel according to an embodiment of the present application, and FIG. 18 is a schematic structural diagram of details of one of the light-emitting devices of FIG. 17. Referring to FIG. 17, the display panel 20 includes a driving backplane 27 and light-emitting devices 28 disposed on a side of the driving backplane 27. The driving backplane 27 includes a plurality of bonding electrode pairs, and each bonding electrode pair includes a first bonding electrode 271 and a second bonding electrode 272 insulated from each other. The first bonding end 24 at the top of the display panel 20 may be disposed in the same layer as the first bonding electrode 271 and the second bonding electrode 272. The light-emitting devices 28 are bonded to the driving backplane 27 by corresponding bonding electrode pairs. Referring to FIG. 18, each of the light-emitting devices 28 includes a first electrode 221 and a second electrode 222 that are insulated from each other. The first electrode 221 is electrically connected to the first bonding electrode 271, and the second electrode 222 is electrically connected to the second bonding electrode 272. The light-emitting surface of the light-emitting device 28 faces the driving backplane 27, and the light-emitting device 28 further includes an epitaxial plate 223. The first electrode 221 and the second electrode 222 are disposed on the side of the epitaxial plate 223 away from the driving backplane 27.

The light-emitting surface of the light-emitting device 28 faces the driving backplane 27, so that the light emitted from the light-emitting device 28 can directly pass through the driving backplane 27 to realize the bottom light emission of the display panel 20 while improving the utilization rate of the light emitted from the light-emitting device 28. Since the first electrode 221 and the second electrode 222 are provided on the side of the epitaxial plate 223 away from the driving backplane 27, that is, on the non-light-emitting surface of the light-emitting device 28, it is possible to prevent the first electrode 221 and the second electrode 222 from blocking the light emitted from the light-emitting device 28 to improve the utilization rate of the light emitted from the light-emitting device 28.

With continued reference to FIG. 17, the driving backplane 27 further includes a substrate 40, and a transistor 50 disposed on the substrate 40. The first bonding electrode 271 and the bonding second electrode 222 are disposed on a side of the transistor 50 away from the substrate 40, and the first bonding electrode 271 is electrically connected to the transistor 50.

The substrate 40 may be a rigid base or a flexible base. In a case that the substrate 40 is a rigid base, the rigid base may be a rigid transparent base such as a glass base, a quartz base, or a silicon wafer. In a case that the substrate 40 is a flexible base, the flexible base may be a flexible transparent base such as a Polyimide (PI) film or an ultra-thin glass film.

The driving backplane 27 further includes a light-shielding layer 60 disposed on the substrate 40 and corresponding to the transistor 50, the light-shielding layer 60 is used for shielding the transistor 50 from the light. The transistor 50 includes an active layer 51, a gate electrode 52, a source electrode 54, and a drain electrode 53, and the first bonding electrode 271 is electrically connected to the drain electrode 53. The material of the light-shielding layer 60 includes a light-shielding material such as metal. The material of the active layer 51 includes a semiconductor material such as polysilicon or metal oxide. The materials of the gate electrode 52, the source electrode 54, and the drain electrode 53 include metals such as copper, aluminum, titanium, and molybdenum.

The driving backplane 27 also includes a plurality of insulating layers, such as a buffer layer 41, a gate insulating layer 42, an interlayer insulating layer 43, a passivation layer 44, and a planarization layer 45. Here, the buffer layer 41 covers the light-shielding layer 60 and the substrate 40, and the buffer layer 41 can prevent undesirable impurities or contaminants (such as moisture, oxygen, and the like) from diffusing from the substrate 40 to devices that may be damaged by these impurities or contaminants, while providing a flat top surface.

The active layer 51 is provided on the buffer layer 41, the gate insulating layer 42 is provided on the active layer 51, and the gate electrode 52 is provided on the gate insulating layer 42. The active layer 51 includes a channel, and source and drain areas disposed on two sides of the channel respectively, and the gate electrode 52 and the gate insulating layer 42 are provided corresponding to the channel. The interlayer insulating layer 43 covers the gate electrode 52 and the buffer layer 41. The source electrode 54 and the drain electrode 53 are disposed on the interlayer insulating layer 43. The source electrode 54 is electrically connected to the source area of the active layer 51, and the drain electrode 53 is electrically connected to the drain area of the active layer 51. The passivation layer 44 covers the source electrode 54, the drain electrode 53, and the interlayer insulating layer 43, and the planarization layer 45 covers the passivation layer 44. The first bonding electrode 271 and the second bonding electrode 272 are provided on the planarization layer 45, and the first bonding electrode 271 is electrically connected to the drain electrode 53 through vias through the planarization layer 45 and the passivation layer 44.

The buffer layer 41, the gate insulating layer 42, the interlayer insulating layer 43, and the passivation layer 44 may be a stack of inorganic materials such as silicon nitride (SiNx), silicon oxide (SiOx), or silicon nitride and silicon oxide. The material of the planarization layer 45 includes an organic material such as a photoresist.

The light-emitting devices 28 are provided on the side of the planarization layer 45 away from the substrate 40. The light-emitting device 28 includes a Micro LED chip, a Mini LED chip, an LED chip, or the like. The transistor 50 is used to control the turn-on and turn-off of a corresponding light-emitting device 28. Specifically, the first electrode 221 of the light-emitting device 28 is bonded to the driving backplane 27 through the first bonding electrode 271, and is electrically connected to the transistor 50 through the first bonding electrode 271; and the second electrode 222 of the light-emitting device 28 is bonded to the driving backplane 27 through the second bonding electrode 272. Alternatively, the first electrode 221 is a cathode, and the second electrode 222 is an anode.

The display panel 20 further includes a first connection line 31 connected between the first electrode 221 and the first bonding electrode 271, and a second connection line 32 connected between the second electrode 222 and the second bonding electrode 272. The material of the first connection line 31, the second connection line 32, the first bonding electrode 271, the second bonding electrode 272, the first electrode 221, and the second electrode 222 may be transparent conductive material such as indium tin oxide (ITO).

Further, the light-emitting device 28 further includes an insulating protective layer 224 covering the epitaxial plate 223 and exposing the first electrode 221 and the second electrode 222. The first connection line 31 and the second connection line 32 are provided on the side of the insulating protective layer 224 away from the epitaxial plate 223. That is, the insulating protective layer 224 covers all areas on the epitaxial plate 223 except the first electrode 221 and the second electrode 222, to avoid short circuits between the first connection line 31 and the epitaxial plate 223, and between the second connection line 32 and the epitaxial plate 223. The insulating protective layer 224 may be a stack of inorganic materials such as silicon nitride (SiNx), silicon oxide (SiOx), or silicon nitride and silicon oxide.

Referring to FIG. 18, the epitaxial plate 223 includes an N-type semiconductor layer 2231, a P-type semiconductor layer 2232, and a quantum well layer 2233 disposed between the N-type semiconductor layer 2231 and the P-type semiconductor layer 2232. The P-type semiconductor layer 2232 is disposed on the side of the N-type semiconductor layer 2231 away from the driving backplane 27, the first electrode 221 is electrically connected to the N-type semiconductor layer 2231, and the second electrode 222 is electrically connected to the P-type semiconductor layer 2232. The N-type semiconductor layer 2231 includes a protrusion beyond the boundary of the quantum well layer 2233, the first electrode 221 is disposed on the side of the protrusion away from the driving backplane 27, and the second electrode 222 is disposed on the side of the P-type semiconductor layer 2232 away from the quantum well layer 2233. The orthographic projection of the first electrode 221 on the driving backplane 27 is spaced from the orthographic projection of the second electrode 222 on the driving backplane 27.

To further improve the utilization of the emitted light of the light-emitting device 28, the orthographic projection of the transistor 50 on the substrate 40 is spaced from the orthographic projection of the epitaxial plate 223 on the substrate 40. In the present application, the term “spaced from” defines that the orthographic projections of the two structures on the same surface are not overlapped. For example, in the present embodiment, “the orthographic projection of the transistor 50 on the substrate 40 is spaced from the orthographic projection of the epitaxial plate 223 on the substrate 40” means that the orthographic projection of the transistor 50 on the substrate 40 is not overlapped with the orthographic projection of the epitaxial plate 223 on the substrate 40. As such, the transistor 50 is prevented from blocking the light emitted from the light-emitting device 28.

Further, the display panel 20 further includes an encapsulation layer 23 covering the light-emitting devices 28 and the driving backplane 27. The encapsulation layer 23 serves to protect the light-emitting devices 28, and prevent water and oxygen from intruding into the light-emitting devices 28. Alternatively, the material of the encapsulation layer 23 is selected to have reflective properties to further improve the utilization of the light emitted from the light-emitting devices 28.

The present embodiment adopts the bottom light-emitting display panel, the light-emitting surface of the light-emitting device faces toward the driving backplane, and the first electrode and the second electrode are both disposed on the side of the epitaxial plate away from the driving backplane. Therefore, the first electrode and the second electrode do not block the light emitted from the light-emitting device. In this way, the light output utilization rate of the bottom light-emitting display panel can be improved, and the situation that the light output utilization rate is low due to the fact that the bottom electrode of the flip chip in the bottom light-emitting display panel blocks out the light from the chip is improved.

Embodiments of the present application further provides a spliced display device. As shown in FIG. 19, the spliced display device provided in the embodiment of the present application includes a plurality of display devices 100 spliced together. Each display device 100 may be the display device in the above-described embodiment, and details are not described herein.

As above, although the present application has been disclosed as the above-described embodiments, the above-described embodiments are not intended to limit the present application. Those of ordinary skill in the art may make various changes and modifications without departing from the spirit and scope of the present application, and therefore the scope of protection of the present application is as defined in the claims.

What is claimed is:

1. A chip-on-film structure, comprising:
a base, wherein the base includes a first surface and a second surface oppositely disposed;
a first circuit covering the first surface, wherein the first circuit includes a driving chip bonding area;
a display panel bonding end disposed on the second surface; and
a first conductive portion connected to the first circuit and the display panel bonding end respectively.

2. The chip-on-film structure of claim 1, wherein the first conductive portion extends through the base.

3. The chip-on-film structure of claim 1, wherein the base further comprises a third surface and a fourth surface, the third surface is connected to the first surface and the second surface, the fourth surface is connected to the first surface and the second surface; and the first conductive portion covers the third surface.

4. The chip-on-film structure of claim 1, wherein the display panel bonding end and the first conductive portion are overlapped in a target direction, and the target direction is parallel to the second surface.

5. The chip-on-film structure of claim 1, wherein the display panel bonding end is spaced apart from the first conductive portion in a target direction, and the target direction is parallel to the second surface;
wherein the chip-on-film structure further includes a second circuit, the second circuit at least partially covers the second surface, the display panel bonding end is disposed on a side of the second circuit away from the base, and the first conductive portion is connected to the display panel bonding end through the second circuit.

6. The chip-on-film structure of claim 5, wherein the chip-on-film structure further comprises a heat insulating layer; and the heat insulating layer is disposed on a side of the second circuit away from the base.

7. The chip-on-film structure of claim 1, wherein the chip-on-film structure further comprises a first protective layer; and the first protective layer is disposed on a side of the first circuit away from the base.

8. The chip-on-film structure of claim 6, wherein the chip-on-film structure further comprises a second protective layer; and the second protective layer is positioned between the second circuit and the heat insulating layer.

9. The chip-on-film structure of claim 1, wherein the first circuit further comprises a circuit board bonding area; and the circuit board bonding area and the display panel bonding end are respectively disposed close to opposite ends of the base.

10. The chip-on-film structure of claim 1, wherein the chip-on-film structure further comprises a driving chip and a circuit board, the driving chip is disposed in the driving chip bonding area and is connected to the first circuit, and the circuit board is disposed in the circuit board bonding area and is connected to the first circuit.

11. A display device, comprising:
the chip-on-film structure of claim 1; and
a display panel, wherein the display panel is connected to the display panel bonding end in the chip-on-film structure.

12. The display device of claim 11, wherein the display panel is a top light-emitting display panel, and the display panel includes a second conductive portion;
wherein a top of the light-emitting display panel has a second bonding end, the chip-on-film structure is disposed at bottom of the top light-emitting display panel, and the display panel bonding end faces the display panel and is connected to the second bonding end through the second conductive portion; and
wherein the second conductive portion extends through the display panel or covers a side surface of the display panel.

13. The display device of claim 11, wherein the display panel is a bottom light-emitting display panel;
wherein a top of the bottom light-emitting display panel has a first bonding end, the chip-on-film structure is disposed on top of the display panel, and the display panel bonding end faces the display panel and is connected to the first bonding end.

14. The display device of claim 13, wherein the display panel comprises:
a driving backplane, wherein the driving backplane includes a plurality of bonding electrode pairs, each of the plurality of bonding electrode pairs includes a first bonding electrode and a second bonding electrode insulated from each other; and
light-emitting devices, wherein each of the light-emitting devices is bonded to the driving backplane through a corresponding pair of the plurality of bonding electrode pairs, the light-emitting device includes a first electrode and a second electrode insulated from each other, the first electrode is electrically connected to the first bonding electrode, and the second electrode is electrically connected to the second bonding electrode;
wherein a light-emitting surface of the light-emitting device faces the driving backplane, the light-emitting device further comprises an epitaxial plate, and the first electrode and the second electrode are both disposed on a side of the epitaxial plate away from the driving backplane.

15. The display device of claim 14, wherein the display panel further comprises a first connection line connected between the first electrode and the first bonding electrode, and a second connection line connected between the second electrode and the second bonding electrode.

16. The display device of claim 15, wherein the light-emitting device further comprises an insulating protective layer covering the epitaxial plate and exposing the first electrode and the second electrode, and the first connection line and the second connection line both are provided on a side of the insulating protective layer away from the epitaxial plate.

17. The display device of claim 14, wherein the epitaxial plate comprises an N-type semiconductor layer, a P-type semiconductor layer, and a quantum well layer disposed between the N-type semiconductor layer and the P-type semiconductor layer; the P-type semiconductor layer is disposed on a side of the N-type semiconductor layer away from the driving backplane; the first electrode is electrically connected to the N-type semiconductor layer; and the second electrode is electrically connected to the P-type semiconductor layer.

18. The display device of claim 17, wherein the N-type semiconductor layer includes a projection beyond a boundary of the quantum well layer, the first electrode is provided on a side of the projection away from the driving backplane, and the second electrode is provided on a side of the P-type semiconductor layer away from the quantum well layer.

19. The display device of claim 18, wherein the driving backplane further comprises a substrate, and a transistor disposed on the substrate; the first bonding electrode and the bonding second electrode both are disposed on a side of the transistor away from the substrate; and the first bonding electrode is electrically connected to the transistor.

20. A spliced display device, comprising a plurality of display devices of claim 11.
